(19) United States
(12) Patent Application Publication
(10) Pub. No.: US 2012/0013316 A1
(43) Pub. Date: Jan. 19, 2012

(54) DC-DC CONVERTER

(75) Inventors: Kazutoshi Nakamura, Kanagawa-ken (JP); Daisuke Minohara, Hyogo-ken (JP)

(73) Assignee: KABUSHIKI KAISHA TOSHIBA, Tokyo (JP)

(21) Appl. No.: 13/053,517

(22) Filed: Mar. 22, 2011

(30) Foreign Application Priority Data
Jul. 14, 2010 (JP) 2010-159701

(51) Int. Cl. G05F 1/00

(52) U.S. Cl. 323/271

(57) ABSTRACT

According to one embodiment, a DC-DC converter includes a mounting substrate and a semiconductor device. The semiconductor device includes a first switch element, a second switch element, a first interconnect layer receiving an input potential, a second interconnect layer connected with an inductor, a third interconnect layer receiving a reference potential, and a fourth interconnect layer connected with the inductor. These layers are disposed side by side in one direction on one layer. The mounting substrate includes a fifth interconnect pattern receiving an input potential and disposed adjacently on one side of a mounting region of the semiconductor device, a sixth interconnect pattern receiving a reference voltage and disposed adjacently on the one side of the mounting region, and a seventh interconnect pattern disposed adjacently on one other side opposite to the one side of the mounting region.

### CROSS-REFERENCE TO RELATED APPLICATIONS

This application is based upon and claims the benefit of priority from the prior Japanese Patent Application No. 2010-159701, filed on Jul. 14, 2010; the entire contents of which are incorporated herein by reference.

### FIELD

Embodiments described herein relate generally to a DC-DC converter.

### BACKGROUND

A DC-DC converter includes an input voltage line, a high-side switching element connected in series between a ground that is a reference potential, and a low-side switching element. A DC-DC converter outputs a voltage Vout that is lower than an input voltage Vin to an output line by alternately switching the high-side switching element and the low-side switching element between an ON and an OFF configuration.

The high-side switching element includes a p-channel MOSFET (metal oxide semiconductor field effect transistor), or an n-channel MOSFET. An n-channel MOSFET is used in the low-side channel element. Herein, the configuration in which a p-channel MOSFET is used in the high-side switching element will be described.

The source of the high-side switching element is connected with the input voltage line. Furthermore the drain of the high-side switching element is connected to the drain of the low-side switching element.

The source of the low-side switching element is connected to the ground. A connecting node between the high-side switching element and the low-side switching element is connected to one end of the inductor that acts as an inductive load. The other end of the inductor is connected to an output line. A smoothing capacitor is connected between the output line and the ground to prevent sharp short-term variation of the output voltage.

In this type of DC-DC converter, the respective gates for the high-side switching element and the low-side switching element are connected to a control circuit. A gate control signal having a substantially reverse phase is supplied from the control circuit to the gate of the high-side switching element, and to the gate of the low-side switching element. In this manner, the high-side switching element and the low-side switching element can be controlled to an ON and OFF configuration.

In the DC-DC converter, the high-side switching element, the low-side switching element and the driver circuit are components that are contained in respectively separate packages, and the respective components are mounted on a printed board. Each component is connected electrically by an interconnect on the printed board.

In order to reduce the number of mounted components and to reduce the mounting surface area, the driver circuit for driving of the high-side switching element and the low-side switching element has an on-chip configuration, and in addition a bump connection is employed to reduce the interconnect resistance.

However, there is still a margin for improvement in relation to further reducing the interconnect resistance, and reducing the parasitic inductance that results in spike noise in switching elements connected to the inductor.

### BRIEF DESCRIPTION OF THE DRAWINGS

FIG. 1 is a schematic perspective view illustrating a DC-DC converter according to a first embodiment;

FIG. 2 is a schematic plan view illustrating a semiconductor device used in the DC-DC converter according to the first embodiment;

FIG. 3 is a schematic plan view illustrating a mounting substrate used in a DC-DC converter 110 according to the first embodiment;

FIG. 4 is a schematic plan view illustrating an interconnect layout on the semiconductor substrate in the broken line frames A, B in FIG. 2;

FIG. 5 is a schematic sectional view illustrating the connection configuration between the semiconductor device and the mounting substrate;

FIG. 6 is a circuit diagram illustrating the circuit configuration of the DC-DC converter;

FIG. 7 is a schematic sectional view of the first switch element;

FIG. 8 is a schematic sectional view of the second switch element;

FIG. 9 illustrates the signal of the node V_{SW} of the DC-DC converter according to the first embodiment;

FIG. 10 is a schematic plan view illustrating a semiconductor device used in a DC-DC converter according to a second embodiment;

FIG. 11 is a schematic plan view illustrating mounting substrate used in the DC-DC converter according to the second embodiment;

FIG. 12 illustrates the signal of the node V_{SW} of the DC-DC converter according to the second embodiment;

FIG. 13 is a schematic plan view illustrating another configuration of the semiconductor device used in the DC-DC converter according to the second embodiment;

FIG. 14 is a schematic plan view of the first switch element;

FIG. 15 is a schematic plan view of the second switch element;

FIG. 16 is a schematic sectional view along the line Y1-Y1′ in FIG. 14; and

FIG. 17 is a schematic sectional view along the line Y2-Y2′ in FIG. 15.

### DETAILED DESCRIPTION

In general, according to one embodiment, a DC-DC converter includes a mounting substrate and a semiconductor device mounted on the mounting substrate. The semiconductor device includes a first switch element mounted on a semiconductor substrate, a second switch element mounted on the semiconductor substrate, a first interconnect layer electrically connected with the first switch element and receiving an input potential, a second interconnect layer electrically connected with the first switch element and connected with an inductor, a third interconnect layer electrically connected with the second switch element and receiving a reference potential, and a fourth interconnect layer electrically connected with the second switch element and connected with the inductor. The first interconnect layer, the second interconnect layer, the third interconnect layer, and the fourth interconnect layer are disposed side by side in one direction in the semiconductor substrate. The mounting substrate includes a first interconnect pattern connected with the first interconnect layer, a second interconnect pattern connected with the second interconnect layer, a third interconnect pattern connected with the third interconnect layer, a fourth interconnect pattern connected with the fourth interconnect layer, a fifth interconnect pattern receiving an input potential, electrically connected with the first interconnect pattern, and disposed adjacently on one side of a mounting region of the semiconductor device, a sixth interconnect pattern receiving a reference voltage, electrically connected with the third interconnect pattern, and disposed adjacently on the one side of the mounting region, and a seventh interconnect pattern electrically connected with the second interconnect pattern and the fourth interconnect pattern, and disposed adjacently on one other side opposite to the one side of the mounting region.

Various embodiments will be described hereinafter with reference to the accompanying drawings.

The figures are schematic or conceptual, and a relationship between thickness and width in each component, a ratio or coefficient of size between components may not necessarily be the same as the actual configuration. Furthermore, even when representing the same component, the dimension, and ratio or coefficient may be represented differently in different figures.

In the specification and the figures of the application, the same reference numbers are applied to the same elements already described in relation to previous figures, and detailed description will not be repeated as appropriate.

### First Embodiment

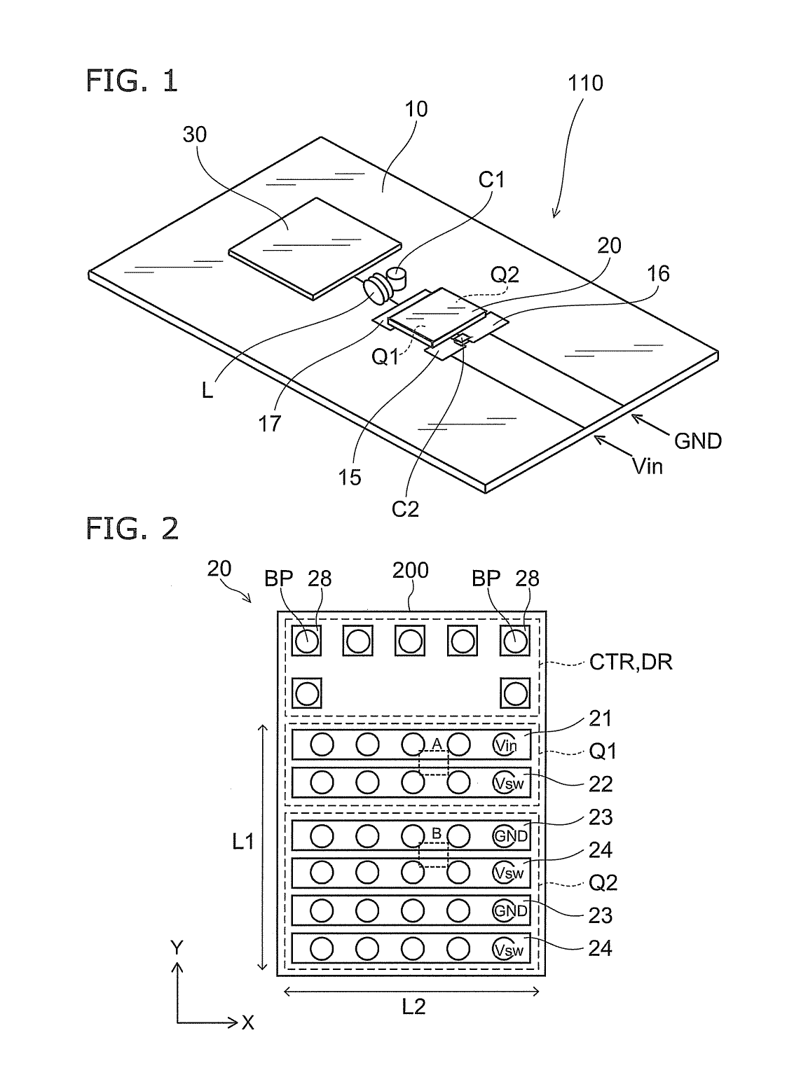

FIG. 1 is a schematic perspective view illustrating a DC-DC converter according to a first embodiment.

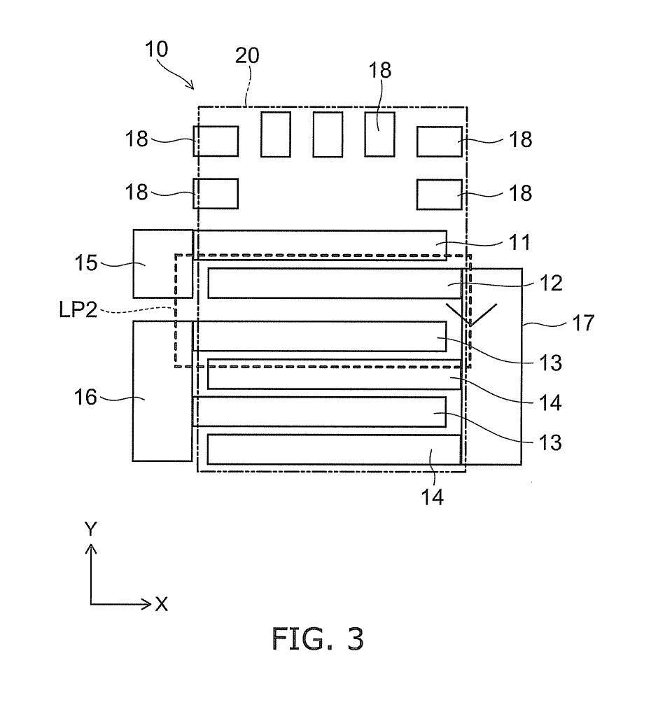

FIG. 2 is a schematic plan view illustrating a semiconductor device used in the DC-DC converter according to the first embodiment.

FIG. 3 is a schematic plan view illustrating a mounting substrate used in the DC-DC converter according to the first embodiment.

The DC-DC converter 110 according to the embodiment includes the mounting substrate 10 and the semiconductor device 20.

The semiconductor device 20 includes a first switch element Q1 and a second switch element Q2 that are the main constituent elements of the DC-DC converter 110. The first switch element Q1 is a high-side switching element. The second switch element Q2 is a low-side switching element.

The first switch element Q1 is a p-channel MOSFET that includes a gate, a source and a drain that are formed on a semiconductor substrate 200. The second switch element Q2 is an n-channel MOSFET that includes a gate, a source and a drain that are formed on the semiconductor substrate 200.

The semiconductor device 20 includes a first interconnect layer 21 that is electrically connected with the first switch element Q1 and receives an input potential Vin, a second interconnect layer 22 that is electrically connected with the first switch element Q1 and is connected with an inductor L, a third interconnect layer 23 that is electrically connected with the second switch element Q2 and receives a reference potential (ground potential in the embodiment) GND, and a fourth interconnect layer 24 that is electrically connected with the second switch element Q2 and is connected with the inductor L.

The semiconductor substrate 200 of the semiconductor device 20 has, for example, a rectangular external shape. A first direction is configured along the short side of the rectangle (x direction) and a second direction is configured along the long side of the rectangle (y direction). In other words, the first interconnect layer 21, the second interconnect layer 22, the third interconnect layer 23 and the fourth interconnect layer 24 respectively extend with a length L2 along the x directions. Furthermore, the first interconnect layer 21, the second interconnect layer 22, the third interconnect layer 23 and the fourth interconnect layer 24 are aligned along the y direction with a length of L1. Herein, L1>L2.

The first interconnect layer 21, the second interconnect layer 22, the third interconnect layer 23 and the fourth interconnect layer 24 are provided, for example, as the uppermost layer of the multiple interconnect layers provided on the semiconductor substrate 200. As illustrated in FIG. 2, the first interconnect layer 21, the second interconnect layer 22, the third interconnect layer 23 and the fourth interconnect layer 24 are provided on the connection surface side of the semiconductor device 20, and are exposed and project from the connection surface. The first interconnect layer 21, the second interconnect layer 22, the third interconnect layer 23 and the fourth interconnect layer 24 may be configured so that only the portion provided with a bump electrode (projection electrode) as described below is exposed.

The first interconnect layer 21, the second interconnect layer 22, the third interconnect layer 23 and the fourth interconnect layer 24 respectively extend along the x direction of the semiconductor substrate 200. The first interconnect layer 21, the second interconnect layer 22, the third interconnect layer 23 and the fourth interconnect layer 24 are disposed side by side on the y direction that is orthogonal to the x direction in the same layer of the semiconductor substrate 200.

In the example illustrated in FIG. 2, one first interconnect layer 21 and one second interconnect layer 22 are respectively provided, and two third interconnect layers 23 and fourth interconnect layers 24 are respectively provided. Multiple first interconnect layers 21, second interconnect layers 22, third interconnect layers 23 and fourth interconnect layers 24 may be provided in the semiconductor device 20. When multiple interconnect layers are respectively provided, the first interconnect layer 21 and the second interconnect layer 22 are disposed alternately along the y direction. The third interconnect layer 23 and the fourth interconnect layer 24 are alternately disposed along the y direction.

A control circuit CTR and a drive circuit DR for applying a control signal to gates of the first switch element Q1 and the second switch element Q2 are provided on the semiconductor substrate 200 of the semiconductor device 20. Multiple external signal interconnect layers 28 are connected to the control circuit CTR and the drive circuit DR.

A bump electrode BP for connection with the interconnect pattern of the mounting substrate 10 is provided on the first interconnect layer 21, the second interconnect layer 22, the third interconnect layer 23, the fourth interconnect layer 24 and the external signal interconnect layer 18. Not less than one bump electrode BP is provided for one interconnect layer. For example, one bump electrode BP is provided respectively for the multiple external signal interconnect layers 28. In addition, multiple bump electrodes BP (five are illustrated in FIG. 2) are provided along the direction of extension in the extended first interconnect layer 21, the second interconnect layer 22, the third interconnect layer 23, and the fourth interconnect layer 24. Multiple bumps are provided since the current flow in the first interconnect layer 21, the second interconnect layer 22, the third interconnect layer 23, the fourth interconnect layer 24 is relatively large in comparison to the external signal interconnect layer.

The mounting substrate 10 includes a first interconnect pattern 11 that is connected with the first interconnect layer 21, a second interconnect pattern 12 that is connected with the second interconnect layer 22, a third interconnect pattern 13 that is connected with the third interconnect layer 23, a fourth interconnect pattern 14 that is connected with the fourth interconnect layer 24, a fifth interconnect pattern 15 that is electrically connected with the first interconnect layer 11 and receives an input potential Vin, a sixth interconnect pattern 16 that is electrically connected with the third interconnect layer and receives a reference potential, and a seventh interconnect pattern 17 that is electrically connected with the second interconnection layer 12 and the fourth interconnect layer 14. The first interconnect pattern 11 to the seventh interconnect pattern 17 are formed of, for example, copper (Cu).

FIG. 3 illustrates the layout of an interconnect pattern in the mounting substrate 10. The first interconnection pattern 11, the second interconnection pattern 12, the third interconnection pattern 13, and the fourth interconnection pattern 14 respectively extend in accordance with the first interconnect layer 21, the second interconnect layer 22, the third interconnect layer 23, and the fourth interconnect layer 24 of the semiconductor device 20.

The fifth interconnect pattern 15 is disposed adjacent to a first side relative to the mounting region of the semiconductor device 20. In other words, the fifth interconnect pattern 15 is connected with one end of the first interconnect pattern 11, and is disposed on the first side relative to the mounting region.

The sixth interconnect pattern 16 is disposed adjacent to the fifth interconnect pattern 15 on the first side relative to the mounting region of the semiconductor device 20. The sixth interconnect pattern 16 is connected to one end of the third interconnect pattern and is disposed on the first side of the mounting region.

The seventh interconnect pattern 17 is disposed adjacent to a second side opposite to the first side of the mounting region of the semiconductor device 20. In other words, the seventh interconnect pattern 17 is connected to one other end of the second interconnect pattern 12 and the fourth interconnect pattern 14, and is disposed on the second side of the mounting region. The seventh interconnect pattern 17 is a pattern that combines the second interconnect pattern 12 and the fourth interconnect pattern 14.

Multiple gate interconnect patterns 18 connected with multiple external signal interconnect layers 28 of the semiconductor device 20 are provided on the mounting substrate 10.

The semiconductor device 20 is mounted in a facedown configuration through the bump electrode BP on the mounting substrate 10 as described above. The facedown mounting of the semiconductor device 20 enables connection between each of the first interconnect layer 21, the second interconnect layer 22, the third interconnect layer 23, the fourth interconnect layer 24, and the external signal interconnect layer 28 of the semiconductor device 20, and each of the first interconnect pattern 11, the second interconnect pattern 12, the third interconnect pattern 13, the fourth interconnect pattern 14, and the gate interconnect pattern 18 of the mounting substrate 10.

As illustrated in FIG. 1, the mounting substrate 10 is connected with a load circuit 30 in addition to the semiconductor device 20. A capacitor C1 and an inductor L are connected between the load circuit 30 and the seventh interconnect pattern 17 of the semiconductor device 20. The inductor L is used as a choke coil for the DC-DC converter 110. One end of the inductor L is connected with the seventh interconnect pattern 17, and the other end is connected to the load circuit 30. The capacitor C1 is used as an output capacitor for the DC-DC converter 110, and is used to stabilize load response characteristics, output ripple, and the like. One end of the capacitor C1 is connected between the inductor L and the seventh interconnect pattern 17, and the other end is grounded.

A smoothing capacitor C2 is connected between the fifth interconnect pattern 15 and the sixth interconnect pattern 16 provided on the mounting substrate 10. Since the fifth interconnect pattern 15 and the sixth interconnect pattern 16 are adjacent, the capacitor C2 is connected to straddle the fifth interconnect pattern 15 and the sixth interconnect pattern 16. Since the second interconnect layer 22 and the fourth interconnect layer 24 of the semiconductor device 20 in the DC-DC converter 110 according to the embodiment are configured by the seventh interconnect pattern 17 of the mounting substrate 10, a reduction in interconnection resistance is achieved in comparison to configuring the second interconnect layer 22 and the fourth interconnect layer 24 in the semiconductor device 20, that is to say, by an interconnect on the semiconductor substrate 200.

Since multiple third interconnect layers 23 of the semiconductor device 20 are configured by the sixth interconnect pattern 16 of the mounting substrate 10 in the DC-DC converter 110 according to the embodiment, a reduction in interconnection resistance is achieved in comparison to configuring multiple third interconnect layers 23 in the semiconductor device 20 (the interconnect of the semiconductor substrate 200). In the embodiment, although one first interconnect layer 21 is provided, when multiple layers are provided, the layers are configured using the fifth interconnect pattern 15 of the mounting substrate 10. In this manner, a reduction in interconnection resistance is achieved.

The current flowing in the interconnect layers 16, 17 is large when compared with the current in the interconnect layers 13, 14. Therefore, the width of the interconnect layers 16, 17 must be increased to reduce interconnection resistance.

Consequently, since the fifth interconnect pattern 15, the sixth interconnect pattern 16 and the seventh interconnect pattern 17 are provided adjacent to the first side of the mounting region, there is no effect on the size of the semiconductor device 20 even when the width of the interconnect patterns is varied. In other words, even when the width of the fifth interconnect pattern 15, the sixth interconnect pattern 16 and the seventh interconnect pattern 17 is increased to achieve an even greater reduction in interconnection resistance, there is no effect on the size of the semiconductor device 20.

The fifth interconnect pattern 15 and the sixth interconnect pattern 16 are disposed adjacently on the mounting substrate 10 in the DC-DC converter 110 according to the embodiment. In this manner, there is almost no requirement to manipulate the interconnect when connecting the capacitor C2 between the fifth interconnect pattern 15 and the sixth interconnect pattern 16. Therefore, parasitic inductance produced by manipulating the interconnect can be suppressed.

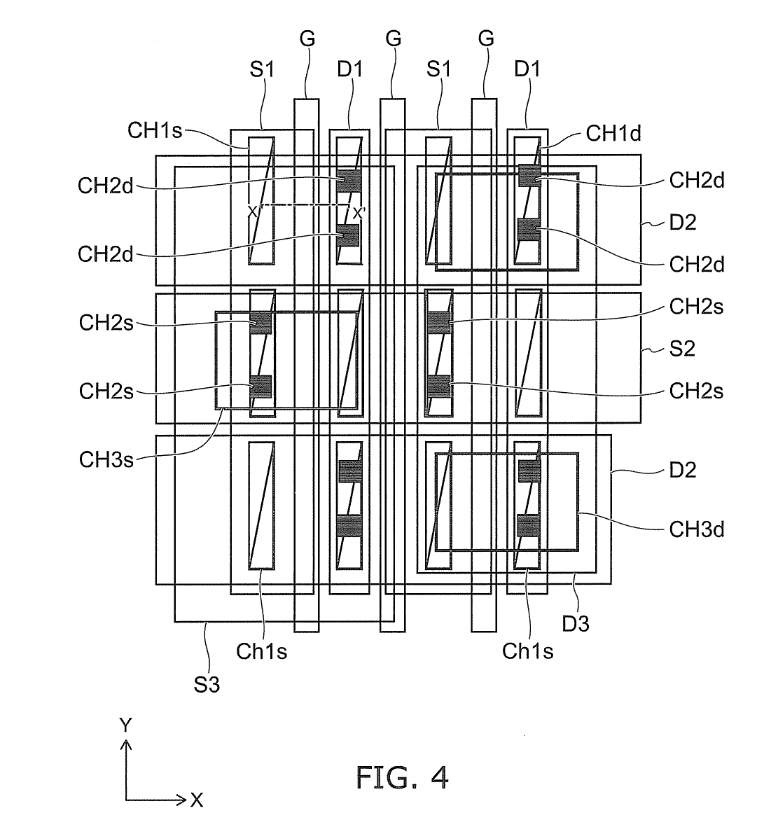

FIG. 4 is a schematic plan view illustrating the interconnect layout on the semiconductor substrate in the broken line frames A, B in FIG. 2.

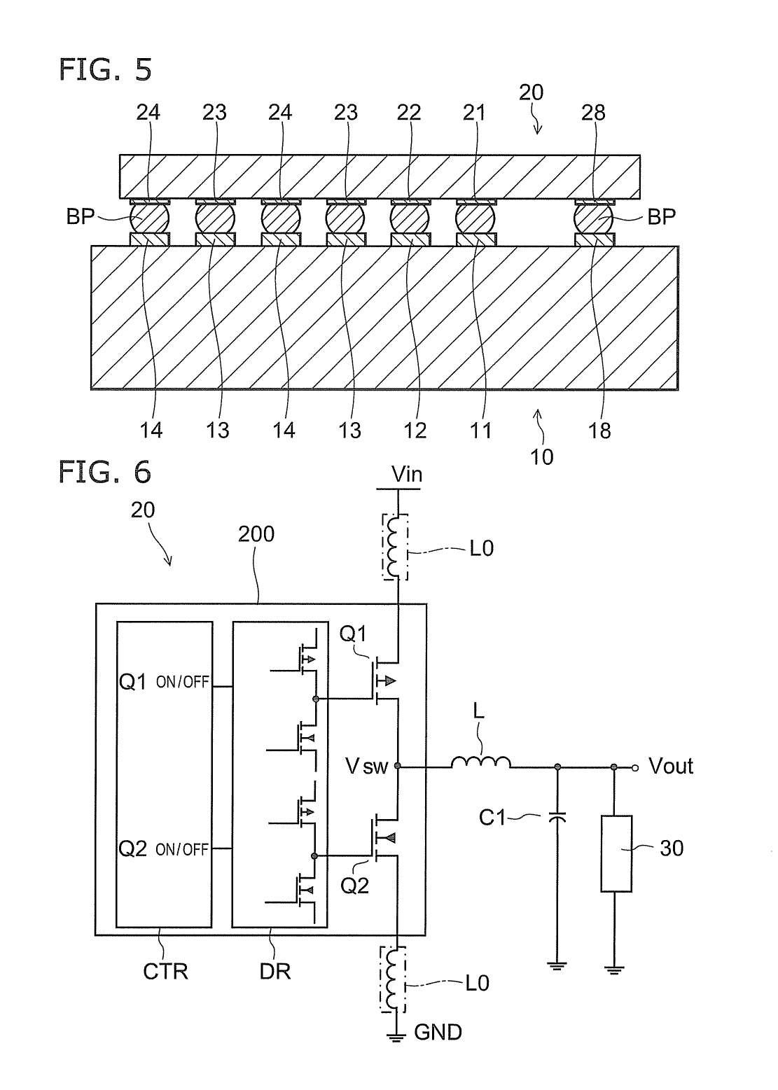

FIG. 5 is a schematic sectional view illustrating the connection configuration between the semiconductor device and the mounting substrate.

FIG. 6 is a circuit diagram illustrating the circuit configuration of the DC-DC converter.

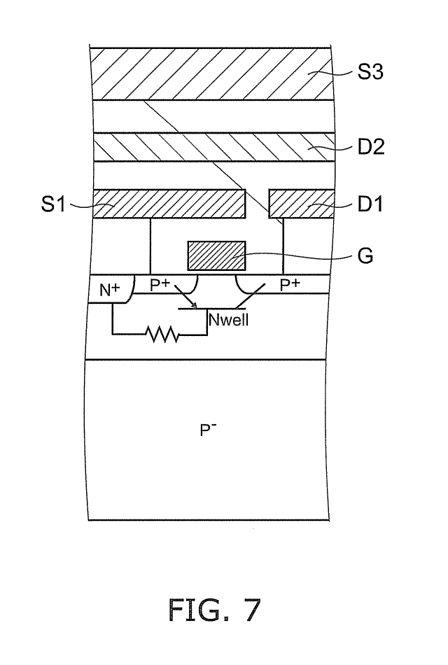

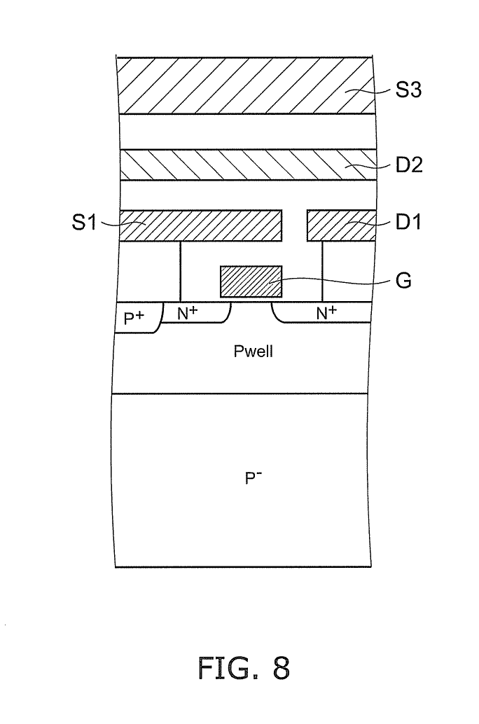

FIG. 7 and FIG. 8 are schematic sectional views along the line X-X′ in FIG. 4. FIG. 7 is a schematic sectional view of the first switch element. FIG. 8 is a schematic sectional view of the second switch element.

In FIG. 7 and FIG. 8, only the interconnect layer is denoted by hatching and other aspects are omitted.

FIG. 4 is a through-view of the multilayer interconnect layout. The interconnect layout illustrated in FIG. 4 is a three-layered interconnect structure. Multiple source regions and multiple drain regions are respectively formed in a striped configuration in the semiconductor substrate 200 in the first switch element Q1 and the second switch element Q2 in a MOSFET configuration. The multiple source regions and multiple drain regions are disposed alternately in a direction that is orthogonal to the stripes. A gate region is provided between the alternately disposed source regions and drain regions.

As illustrated in FIG. 7, p⁺-type source regions and p⁺-type drain regions are provided in a striped configuration at a predetermined interval in an n-type well provided in the semiconductor substrate 200 in the first switch element. As illustrated in FIG. 8, n⁺-type source regions and n⁺-type drain regions are provided in a striped configuration at a predetermined interval in a p-type well provided in the semiconductor substrate 200 in the second switch element.

The space between the alternately disposed source regions and drain regions is a channel region. A gate electrode G is configured in a striped configuration through the gate insulating film on the channel region. The source electrode and the drain electrode are provided on the gate interconnect G to form a three-layered structure. The first interconnect layer includes a first source interconnect layer S1 provided along an upper portion of the source region, and a first drain interconnect layer D1 provided along an upper portion of the drain region. The first source interconnect layer S1 is connected to the source region through the contact CH1s. Contacts CH1s are provided at multiple positions along the source region. The first drain interconnect layer D1 is connected to the drain region through the contact CH1d. The contact CH1d is provided at a plurality of positions along the drain region.

The second interconnect layer includes a second source interconnect layer S2 provided though an interlayer insulating film on the first source interconnect layer S1, and a second drain interconnect layer D2 provided though an interlayer insulating film on the first drain interconnect layer D1. The second source interconnect layer S2 is disposed in a direction orthogonal to the first source interconnect layer S1. The width of the second source interconnect layer S2 is wider than that of the first source interconnect layer S1. The second source interconnect layer S2 is connected to the first source interconnect layer S1 through the contact CH2s. The second drain interconnect layer D2 is disposed in a direction orthogonal to the first drain interconnect layer D1. The width of the second drain interconnect layer D2 is wider than that of the first drain interconnect layer D1. The second drain interconnect layer D2 is connected to the first drain interconnect layer D1 through the contact CH2d. The second source interconnect layer S2 is alternately disposed with the second drain interconnect layer D2.

The third interconnect layer includes a third source interconnect layer S3 provided though an interlayer insulating film on the second source interconnect layer S2, and a third drain interconnect layer D3 provided though an interlayer insulating film on the second drain interconnect layer D2. The third source interconnect layer S3 is disposed in a direction orthogonal to the second source interconnect layer S2. The width of the third source interconnect layer S3 is wider than that of the second source interconnect layer S2. The third source interconnect layer S3 is connected to the second source interconnect layer S2 through the contact CH3s. The third drain interconnect layer D3 is disposed in a direction orthogonal to the second drain interconnect layer D2. The width of the third drain interconnect layer D3 is wider than that of the second drain interconnect layer D2. The third drain interconnect layer D3 is connected to the second drain interconnect layer D2 through the contact CH3d. The third source interconnect layer S3 is alternately disposed with the third drain interconnect layer D3.

In other words, the interconnect width in the three-layered structure progressively increases from the first interconnect layer to the third interconnect layer. The three-layered structure is configured so that the third source interconnect layer S3 and the third drain interconnect layer D3 in the first switch element Q1 respectively correspond to the first interconnect layer 21 and the second interconnect layer 22 of the semiconductor device 20. The three-layered structure is configured so that the third source interconnect layer S3 and the third drain interconnect layer D3 in the second switch element Q2 respectively correspond to the third interconnect layer 23 and the fourth interconnect layer 24 of the semiconductor device 20.

As illustrated in FIG. 5, the semiconductor device 20 is connected to the mounting substrate 10 in a facedown configuration through the bump electrode BP. The first interconnect layer 21 corresponding to the third source interconnect layer S3 of the first switch element Q1 is connected to the first interconnect pattern 11 through the bump electrode BR The third interconnect layer 23 corresponding to the third source interconnect layer S3 of the second switch element Q2 is connected to the third interconnect pattern 13 through the bump electrode BR The fourth interconnect layer 24 corresponding to the third source interconnect layer S3 of the second switch element Q2 is connected to the fourth interconnect pattern 14 through the bump electrode BR

The resistance of the first interconnect pattern 11 is lower than the resistance of the first interconnect layer 21. The resistance of the second interconnect pattern 12 is lower than the resistance of the second interconnect layer 22. The resistance of the third interconnect pattern 13 is lower than the resistance of the third interconnect layer 23. The resistance of the fourth interconnect pattern 14 is lower than the resistance of the fourth interconnect layer 24. The resistance is, for example, a sheet resistance.

The first to the fourth interconnect patterns 11 to 14 of the mounting substrate 10 and the first to the fourth interconnect layers 21 to 24 of the semiconductor device 20 are respectively disposed in parallel so that current flows through the bump electrode BP to the first to the fourth interconnect patterns 11 to 14 that have a low resistance at a shortest distance from the first to the fourth interconnect layer 21 to 24, and therefore achieves a reduction in the interconnect resistance.

As illustrated in FIG. 6, the drain of the first switch element Q1 and the drain of the second switch element Q2 in the DC-DC converter form the same node V_{SW}. A current normally flows in the node V_{SW} in a connection mode that is one operating mode of the DC-DC converter. Consequently, the interconnect resistance of the node V_{SW} has a large effect on the conversion efficiency. In the embodiment, the second interconnect layer 22 and the fourth interconnect layer 24 of the semiconductor device 20 corresponding to the node V_{SW} are configured by the seventh interconnect pattern 17 of the mounting substrate 10. In this manner, a reduction in the interconnect resistance is achieved since the line width can be increased and the resistance can be decreased in comparison to configuring the second interconnect layer 22 and the fourth interconnect layer 24 by an interconnect on the semiconductor substrate 200. Moreover a further reduction in the interconnect resistance is achieved since the second interconnect layer 22 and the fourth interconnect layer 24 that have a relatively narrow line width in comparison to the seventh interconnect pattern 17 extend along the short side of the semiconductor substrate 200, and the seventh interconnect pattern 17 that has a relatively large line width are provided to extend in accordance with the long side of the semiconductor substrate 200.

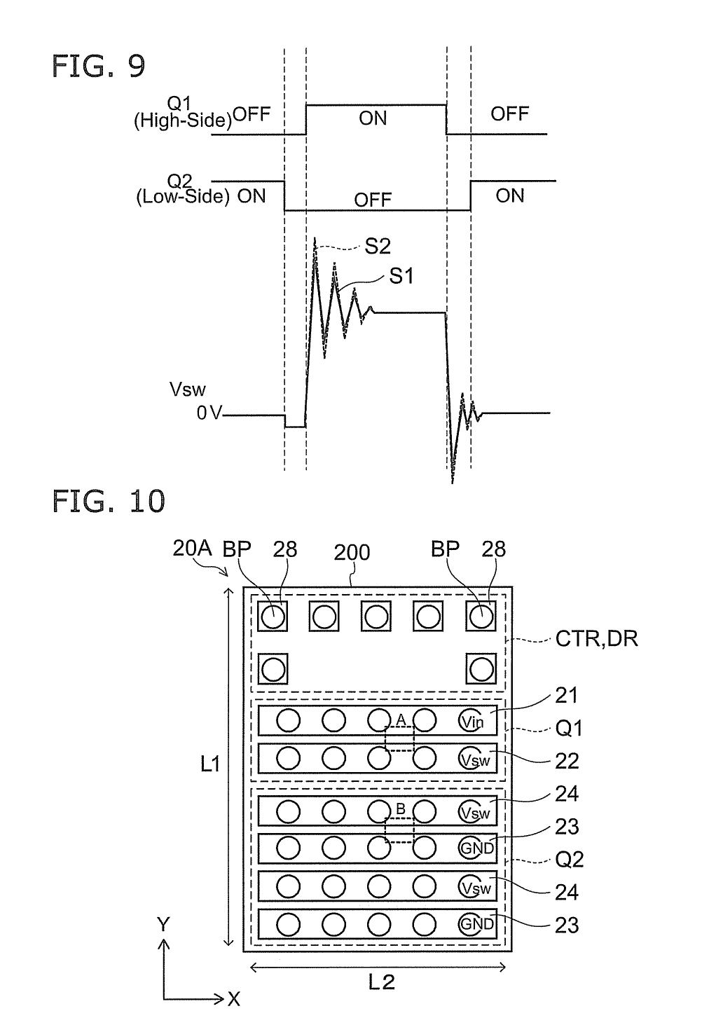

FIG. 9 illustrates the signal of the node V_{SW} of the DC-DC converter according to the first embodiment.

FIG. 9 illustrates the transient characteristics of the signal of the node V_{SW} during ON/OFF switching of the first switch element Q1 that is the high-side switching element and the second switch element Q2 that is the low-side switching element. The signal S1 in the figure illustrates the signal variation in the node V_{SW} when using the configuration in the embodiment, and the signal S2 in the figure illustrates the signal variation in the node V_{SW} when not using the configuration in the embodiment.

In the DC-DC converter according to the embodiment, the fifth interconnect pattern 15 that is subject to an input potential V₁ and the sixth interconnect pattern 16 that is subject to the reference potential GND are adjacently disposed on one side in the mounting region of the semiconductor device 20. Consequently, the interconnect length between the input potential Vᵢₙ and the reference potential GNG can be shortened and parasitic inductance L0 can be reduced. The interconnect resistance of the node V_{SW} can be reduced since the second interconnect layer 22 and the fourth interconnect layer 24 that are electrically connected with the node V_{SW} are configured by a seventh interconnect pattern 17 on the mounting substrate 10. As a result, spike noise during ON/OFF of the first switch element Q1 can be suppressed, and conversion efficiency can be improved.

### Second Embodiment

FIG. 10 is a schematic plan view illustrating a semiconductor device used in a DC-DC converter according to a second embodiment.

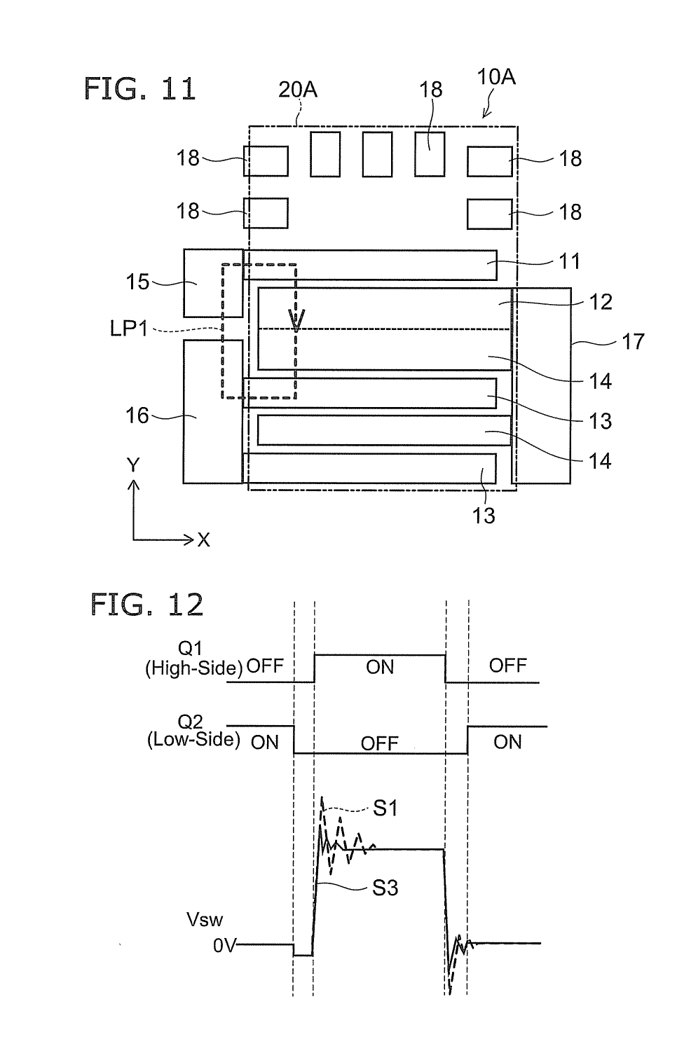

FIG. 11 is a schematic plan view illustrating the mounting substrate used in the DC-DC converter according to the second embodiment.

As illustrated in FIG. 10, a second interconnect layer 22 in the first switch element Q1 and the fourth interconnect layer 24 in the second switch element Q2 are adjacently disposed in the semiconductor device 20A used in the DC-DC converter according to the second embodiment. In other words, the alignment and the order of the third interconnect layer 23 and the fourth interconnect layer 24 in the second switch element Q2 are opposite to the semiconductor device 20 used in the DC-DC converter according to the first embodiment as illustrated in FIG. 2.

As illustrated in FIG. 11, the second interconnect pattern and the fourth interconnect pattern 14 are adjacently integrated on the mounting substrate 10A that is used in the DC-DC converter according to the second embodiment. The integrally-disposed second interconnect pattern 12 and the fourth interconnect pattern 14 are connected with the seventh interconnect pattern 17 on the second side.

When the semiconductor device 20A is mounted on the mounting substrate 10A, the second interconnect layer 22 of the first switch element Q1 and the fourth interconnect layer 24 of the second switch element Q2 are connected to the second interconnect pattern 12 and the fourth interconnect pattern 14 that are integrated on the mounting substrate 10A.

The parasitic inductance between the input potential Vᵢₙ and the first switch element Q1, between the first switch element Q1 and the second switch element Q2, between the second switch element Q2 and the reference potential GND are reduced in the DC-DC converter according to the second embodiment. In other words, the parasitic inductance results from the surface area of the high-frequency current loop LP1 illustrated in FIG. 11. Herein, the high-frequency current loop is produced among the fifth interconnect pattern 15 subjected to the input potential Vᵢₙ, the second interconnect layer 22 of the first switch element Q1 (the second interconnect pattern 12 of the mounting substrate), the fourth interconnect layer of the second switch element Q2 (the fourth interconnect pattern 14 of the mounting substrate), and the sixth interconnect pattern 16 subjected to the reference potential GND.

In the mounting substrate 10 illustrated in FIG. 3, the second interconnect pattern 12 and the fourth interconnect pattern 14 are separated. Therefore, the current loop LP2 describes a large loop from the second interconnect pattern 12 through the seventh interconnect pattern 17 to the fourth interconnect pattern 14.

On the other hand, the second interconnect pattern 12 and the fourth interconnect pattern 14 are integrally provided on the mounting substrate 10A illustrated in FIG. 11. Therefore, the current loop LP1 describes a small loop in the second interconnect pattern 12 and the fourth interconnect pattern 14, that passes through near to the fifth interconnect pattern and the sixth interconnect pattern 16. A reduction in the surface area of the current loop enables a reduction in the parasitic inductance, a reduction in the switching loss and an improvement in the conversion efficiency.

FIG. 12 illustrates the signal of the node V_{SW} of the DC-DC converter according to the second embodiment.

FIG. 12 illustrates the transient characteristics of the signal of the node V_{SW} during ON/OFF switching of the first switch element Q1 that is the high-side switching element and the second switch element Q2 that is the low-side switching element. The signal S3 in the figure illustrates the signal variation in the node V_{SW} when using the configuration in the second embodiment, and the signal S1 in the figure illustrates the signal variation in the node V_{SW} when using the configuration in the first embodiment.

The second embodiment configures the surface area of the current loop LP1 illustrated in FIG. 11 to be smaller than the surface area of the current loop LP2 illustrated in FIG. 3. Therefore, the parasitic inductance can be reduced between the input potential Vᵢₙ and the first switch element Q1, between the first switch element Q1 and a second switch element Q2, and between a second switch element Q2 and the reference potential GND, a spike noise during ON/OFF switching of the first switch element Q1 can be suppressed in comparison to the configuration used in the first embodiment.

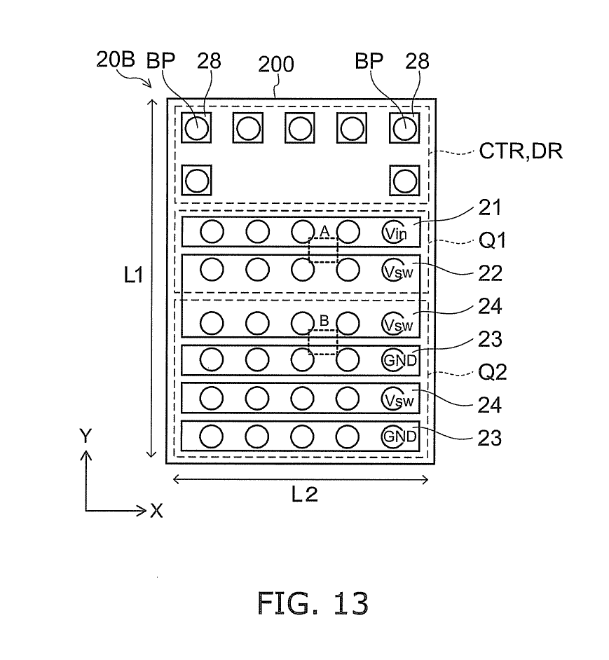

FIG. 13 is a schematic plan view illustrating another configuration of the semiconductor device used in the DC-DC converter according to the second embodiment.

As illustrated in FIG. 13, the second interconnect layer 22 of the first switch element Q1 and the fourth interconnect layer 24 of the second switch element Q2 in the semiconductor device 20B are integrated in the semiconductor substrate 200.

In other words, for simplicity of description, although the second interconnect layer 22 connected with the inductor L of the first switch element Q1 and the fourth interconnect layer 24 connected with the inductor L of the second switch element Q2 are illustrated separately, these components are integrally formed as an interconnect layer.

The mounting substrate that mounts the semiconductor device 20B is the same as the mounting substrate 10A that is illustrated in FIG. 11, and the second interconnect pattern 12 and the fourth interconnect pattern 14 are integrally configured.

Even if the semiconductor device 20B like this, the parasitic inductance can be reduced between the input potential Vᵢₙ and the first switch element Q1, between the first switch element Q1 and the second switch element Q2, between the second switch element Q2 and the reference potential GND. In this manner, a spike noise during ON/OFF switching of the first switch element Q1 can be suppressed in comparison to the configuration used in the first embodiment.

Another example of the DC-DC converter according to the second embodiment will be described below.

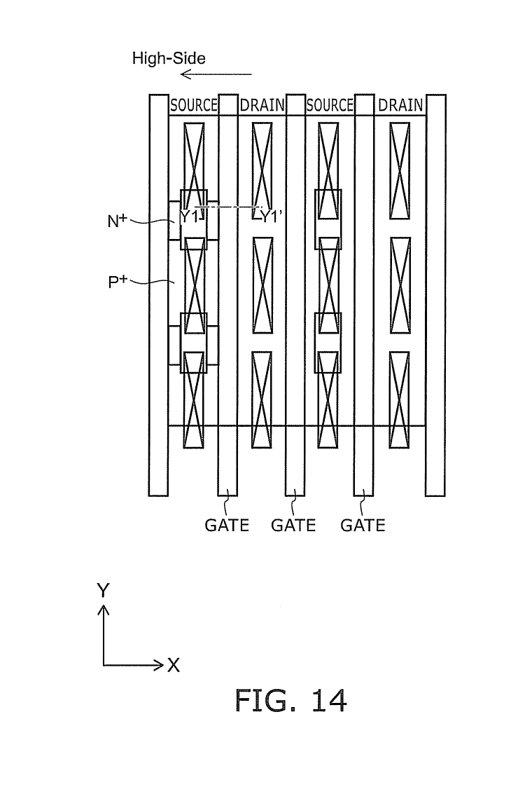

FIG. 14 to FIG. 17 are a schematic view describing another example of the second embodiment.

FIG. 14 is a schematic plan view of the first switch element.

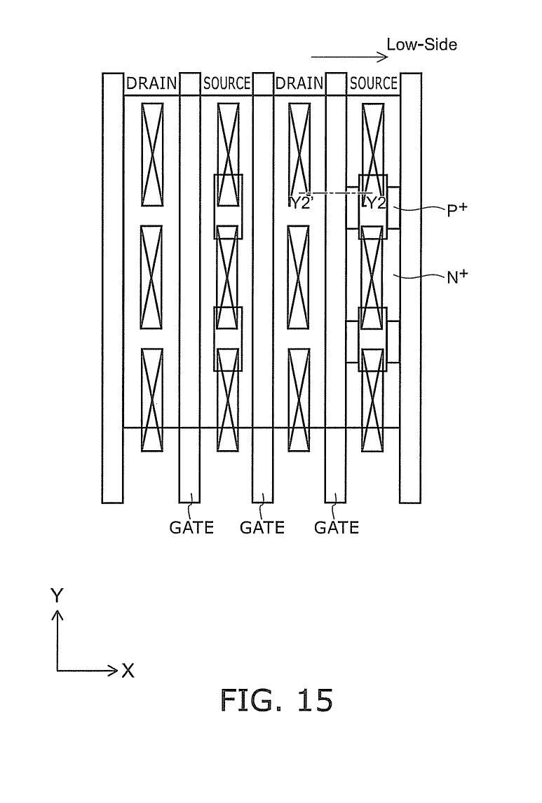

FIG. 15 is a schematic plan view of the second switch element.

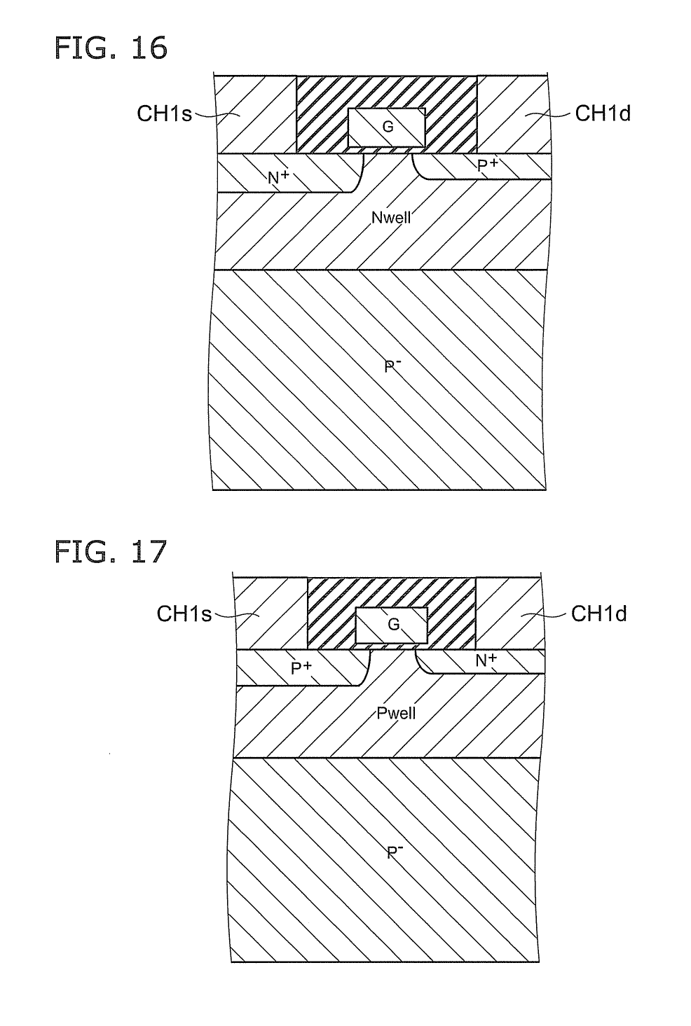

FIG. 16 is a schematic sectional view along the line Y1-Y1′ in FIG. 14.

FIG. 17 is a schematic sectional view along the line Y2-Y2′ in FIG. 15.

Since the surface area of the current loop LP1 is reduced in the configuration of the DC-DC converter according to the second embodiment, when the output current is large, current may become concentrated within the current loop LP1 when switching the first switch element Q1 and the second switch element Q2. When the parasitic bipolar element existing in the MOSFET which configures the first switch element Q1 and the second switch element Q2 turns in ON state, since current is concentrated in ON position during switching, it is important to configure the parasitic bipolar element not to operate.

A portion of the source region of the MOSFET is segmented at the interface portion of the first switch element Q1 and the second switch element Q2. In other words, a region having opposite conductivity (n⁺-type) to the conductivity (p⁺-type) of the drain region is provided in a portion of the extended source region in the first switch element Q1. A region having opposite conductivity (p⁺-type) to the conductivity (n⁺-type) of the drain region is provided in a portion of the extended source region in the second switch element Q2. In this manner, since a channel is reduced, only that part exhibits an increased ON resistance. In other words, mitigation of current concentration is enabled. Since this region is disposed only in the interface portion between the first switch element Q1 and the second switch element Q2, there is not a large effect on the overall ON resistance.

As illustrated in FIG. 14 and FIG. 16, the p⁺-type source region and the p⁺-type drain region are provided in a striped configuration at a predetermined interval in the n-type well provided in the semiconductor substrate 200 in the first switch element Q1. The n⁺-type region is formed in a portion of the p⁺-type source region to thereby separate the source region.

As illustrated in FIG. 15 and FIG. 17, the n⁺-type source region and the n⁺-type drain region are provided in a striped configuration at a predetermined interval in the p-type well provided in the semiconductor substrate 200 in the second switch element Q2. The p⁺-type region is formed in a portion of the n⁺-type source region to thereby separate the source region.

In this manner, when a portion of the source region in the first switch element Q1 and the second switch element Q2 is segmented, a diode is configured in the opposite direction between the source and drain, and the ON resistance of the first switch element Q1 and the second switch element Q2 is increased only in this portion. Therefore, the operation of the parasitic bipolar element is suppressed, and mitigation of the current concentration is achieved.

As described above, according to the DC-DC converter according to the embodiment, since the second interconnect layer 22 and the fourth interconnect layer 24 of the semiconductor device 20 are configured by the seventh interconnect pattern 17 of the mounting substrate 10, and the multiple third interconnect layers 23 are configured by the sixth interconnect pattern 16 of the mounting substrate 10, reduction in the interconnect resistance is achieved.

The fifth interconnect pattern 15 and the sixth interconnect pattern 16 in the mounting substrate 10 of the DC-DC converter according to the embodiment are disposed adjacent to the first side of the mounting region, and consequently, there is almost no need to manipulate the interconnect when connecting the capacitor C2 between the fifth interconnect pattern 15 and the sixth interconnect pattern 16. Therefore a parasitic inductance resulting manipulation of the interconnect can be suppressed.

In this manner, spike noise can be reduced by suppressing the parasitic inductance and reducing the interconnect resistance in the DC-DC converter according to the embodiment.

Although the embodiments and the variations have been described above, the embodiments and variations are merely exemplary, and the invention is not limited thereto. For example, although the above embodiment describes the example of a step-down DC-DC converter, application is also possible to a step-up DC-DC converter. Furthermore, application is also possible to a high-side switching element configured as an n-channel MOSFET.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A DC-DC converter comprising:
a mounting substrate; and
a semiconductor device mounted on the mounting substrate.
the semiconductor device including:
a first switch element mounted on a semiconductor substrate;
a second switch element mounted on the semiconductor substrate;
a first interconnect layer electrically connected with the first switch element and receiving an input potential;
a second interconnect layer electrically connected with the first switch element and connected with an inductor;
a third interconnect layer electrically connected with the second switch element and receiving a reference potential; and
a fourth interconnect layer electrically connected with the second switch element and connected with the inductor,
the first interconnect layer, the second interconnect layer, the third interconnect layer, and the fourth interconnect layer disposed side by side in one direction in the semiconductor substrate,
the mounting substrate including:
a first interconnect pattern connected with the first interconnect layer;
a second interconnect pattern connected with the second interconnect layer;
a third interconnect pattern connected with the third interconnect layer;
a fourth interconnect pattern connected with the fourth interconnect layer;
a fifth interconnect pattern receiving an input potential, electrically connected with the first interconnect pattern, and disposed adjacently on one side of a mounting region of the semiconductor device;
a sixth interconnect pattern receiving a reference voltage, electrically connected with the third interconnect pattern, and disposed adjacently on the one side of the mounting region; and
a seventh interconnect pattern electrically connected with the second interconnect pattern and the fourth interconnect pattern, and disposed adjacently on one other side opposite to the one side of the mounting region.

2. The DC-DC converter according to claim 1 including a projection electrode for connecting the first interconnect layer, the second interconnect layer, the third interconnect layer, and the fourth interconnect layer respectively with the first interconnect pattern, the second interconnect pattern, the third interconnect pattern, and the fourth interconnect pattern.

3. The DC-DC converter according to claim 1, wherein the semiconductor device includes a control circuit configured to input a control signal to the first switch element and the second switch element.

4. The DC-DC converter according to claim 1 including a capacitance element connected between the fifth interconnect pattern and the sixth interconnect pattern.

5. The DC-DC converter according to claim 1, wherein
a resistance of the first interconnect pattern is lower than a resistance of the first interconnect layer,
a resistance of the second interconnect pattern is lower than a resistance of the second interconnect layer,
a resistance of the third interconnect pattern is lower than a resistance of the third interconnect layer, and
a resistance of the fourth interconnect pattern is lower than a resistance of the fourth interconnect layer.

6. The DC-DC converter according to claim 1, wherein
the second interconnect layer is adjacently disposed with the fourth interconnect layer, and
the second interconnect pattern and the fourth interconnect pattern are integrated on the mounting substrate.

7. The DC-DC converter according to claim 1, wherein
the second interconnect layer and the fourth interconnect layer are integrated on the semiconductor device, and
the second interconnect pattern and the fourth interconnect pattern are integrated on the mounting substrate.

8. The DC-DC converter according to claim 6, wherein
a region having conductivity opposite to conductivity of a drain region of the first switch element is provided on a portion of a source region of the first switch element.

9. The DC-DC converter according to claim 7, wherein
a region having conductivity opposite to conductivity of a drain region of the first switch element is provided on a portion of a source region of the first switch element.

10. The DC-DC converter according to claim 6, wherein
a region having conductivity opposite to conductivity of a drain region of the second switch element is provided on a portion of a source region of the second switch element.

11. The DC-DC converter according to claim 7, wherein
a region having conductivity opposite to conductivity of a drain region of the second switch element is provided on a portion of a source region of the second switch element.

12. The DC-DC converter according to claim 1, wherein
the third interconnect layer is provided in a plurality, and the multiple third interconnect layers are connected by the sixth interconnect pattern on the mounting substrate.

13. The DC-DC converter according to claim 1, wherein
an external shape of the semiconductor substrate is rectangular, and
the first interconnect layer, the second interconnect layer, the third interconnect layer, and the fourth interconnect layer extend along a short side of the semiconductor substrate.

14. The DC-DC converter according to claim 1, wherein
an external shape of the semiconductor substrate is rectangular, and
the first interconnect layer, the second interconnect layer, the third interconnect layer, and the fourth interconnect layer extend along a long side of the semiconductor substrate.

15. The DC-DC converter according to claim 1, wherein
an external shape of the semiconductor substrate is rectangular,
the second interconnect layer and the fourth interconnect layer extend along a short side of the mounting substrate, and
the seventh interconnect pattern extend along a long side of the mounting substrate.
